(19) United States
(12) Patent Application Publication
(10) Pub. No.: US 2002/0119663 A1
(43) Pub. Date: Aug. 29, 2002

(54) Method for forming a fine structure on a surface of a semiconductor material, semiconductor materials provided with such a fine structure, and devices made of such semiconductor materials

(76) Inventors: Takashi Matsuura, Sendai-shi (JP); Junichi Murota, Sendai-shi (JP); Mitsuo Miyamoto, Ikoma-shi (JP)

Correspondence Address: Koda & Androlia, Suite 3850, 2029 Century Park East, Los Angeles, CA, 90067-3024, US

(21) Appl. No.: 10/083,615

(22) Filed: Feb. 26, 2002

(30) Foreign Application Priority Data
Feb. 27, 2001 (JP) 2001-051578

(51) Int. Cl. H01L 21/311

(52) U.S. Cl. 438/695

(57) ABSTRACT

A semiconductor material such as Si wafer with a fine structure (porous layer) formed, without using electrical current, on its surface by being contacted with a solution that contains fluoro-complex such as hexafluorotitanate.

### BACKGROUND FOR THE INVENTION

1. Filed of the Invention

The present invention relates to a method for forming a fine structure on a semiconductor material surface, and to semiconductor materials provided with the fine structure formed by such a method, and further to devices that use such semiconductor materials.

2. Prior Art

As a method for forming a fine structure like a porous layer onto a semiconductor material surface, the anodic reaction has been well known so far. In the anodic reaction method, the semiconductor material is dipped in a fluoric-acid-contained solution, and an electrical current is supplied through the semiconductor material, where the semiconductor material functions as an anode, thus forming a porous layer, as shown in FIG. 1. In this anodic reaction method for forming a fine structure, it is inevitable not only to dip the semiconductor material in the fluoric-acid-containing solution but also to make an electrical current line to be connected from the power source outside of the solution to the dipped semiconductor material where the fine structure (porous layer) is to be formed. Therefore, it is impossible by this conventional anodic reaction method to form the fine structure (porous layer) in an isolated semiconductor portion on the insulating layer such as Si on SiO₂ film, because a sufficient electrical current path cannot be connected.

Consequently, it has been laborious to form the fine structure (porous layer) on the semiconductor material surface, and the degree of freedom of the fine structure formation has been limited.

Thus, it has been commonly believed that an electrical current flow is inevitable for forming a fine structure such as a porous layer on a surface of a semiconductor material.

### SUMMARY OF THE INVENTION

It is, therefore, an object of the present invention to provide a method for forming a fine structure (porous layer) on a semiconductor material surface only by contacting the semiconductor material with a solution without a use of an electrical current.

It is another object to provide semiconductor materials on which such a fine structure (porous layer) is formed by such a method and further to provide devices that use such a fine structure.

The method of the present invention for forming a fine structure on a semiconductor material surface is characterized in that the semiconductor material surface is brought to contact with a solution that contains a fluoro-complex.

By this method of the present invention, a fine structure can be easily formed on a semiconductor material surface without applying an electrical current. Thus, it becomes possible to form a fine structure (porous layer) in an isolated semiconductor portion of the insulating layer such as Si on SiO₂ films, because the electrical current path is unnecessary.

The solution that contains the fluoro-complex in the present invention is obtained by dissolving in a hydrofluoric acid, at least, one of:

a metallic element,

alloys containing such a metallic element, and

compounds containing such a metallic element.

For the metallic element, Ti, Mn, Fe, Zr, or Hf is preferable because of its commercial availability.

The solution that contains a fluoro-complex in the method of the present invention can be:

one of solutions of fluorotitanate, fluoromanganate, fluoroferrate, fluorozirconate, fluorohafnate, and a mixture of these, and

a solution obtained by dissolving, at least, one of ammonium salts, alkaline metallic salts, and alkaline earth metallic salts of, at least, one of fluorotitanate, fluoromanganate, fluoroferrate, fluorozirconate, fluorohafnate, and a mixture of these.

In order to enhance the fine structure formation rate and speed up the formation of the fine structure on the semiconductor material, it is preferable to add boric acid or a material, such as aluminum, which is effective for bonding with fluorine, to the solution that contains fluoro-complex.

In the present invention, it is also preferable to form surface patterns on the semiconductor material before executing the above-described fine structure formation method.

In this combined process, the fine structure is formed only in the part of the semiconductor material surface that is defined by the patterning in advance. This combined process easily gives a patterned fine structure on the semiconductor material surface and devices that use the same.

Furthermore, it is also preferable in the present invention to form mask patterns on the semiconductor material surface before executing the above-described fine structure formation method.

In this combined process, the fine structure is formed only in the part of the semiconductor material surface that is not covered with the mask pattern in advance. This combined process also provides a patterned fine structure on the semiconductor material surface and devices that use the same.

It is further preferable to form:

p-type regions [and] or n-type regions,

regions with different impurity concentrations, or

a p-type region and an n-type region

on the semiconductor material surface before executing the above-described fine structure formation methods.

This combined process provides a fine structure that has regions of different conductivity, different conduction type, and/or different porosity on the semiconductor material surface. Thus, this method can provide functional devices that need regions of different conductivity, different conduction type and different porosity simultaneously on the semiconductor material surface.

It is still another object of the present invention to provide semiconductor materials on which a fine structure is formed by one of the above-described fine structure formation method.

These semiconductor materials have a fine structure on the surface and are very easily obtained because they are manufactured without current flow.

It is still another object of the present invention is to provide devices that are made of the semiconductor materials that have a fine structure formed by one of the above-described fine structure formation method.

With such devices of the present invention, optical devices, electronic devices, and opto-electric conversion devices are easily obtainable.

The fine structure formation method and semiconductor materials of the present invention not only replaces the conventional anodic reaction method and the porous layers obtained by the conventional method, respectively, but also is applicable to manufacturing a fine structure in the isolated portion of the semiconductor material. Such application is impossible by the conventional method. Thus, the present invention is widely applicable to optical devices, electronic devices, and opto-electric conversion devices. Moreover, by the formation of the fine structure, it is possible to vary electrical and optical constants of the semiconductor materials such as the refractive index and the dielectric responsibility, and various devices that use such semiconductor materials can be manufactured easily.

In the above-described fine structure formation method, it is preferable to control the concentration and the temperature of the solution that contains the fluoro-complex.

By this control, various fine structures are formed on the semiconductor material depending on the condition of the solution, thus producing different types of fine structure formation on the semiconductor material surface.

It is also preferable that in the above-described fine structure formation method photons (visible light, ultraviolet light, X-ray) be applied on the semiconductor material surface during the solution-contacting process. Especially, the use of light with a higher energy (a shorter wave length) that can induce the inter-band excitation of the carriers is effective.

By this application of light on the semiconductor material, a fine structure is formed under a wider range of condition. Since the carriers on the semiconductor material surface contribute to the fine structure forming reaction, the fine structure formation on the semiconductor material surface can be controlled in various different manners.

It is also preferable in the fine structure formation method of the present invention to supply ultrasonic or mega-sonic to the solution that contains fluoro-complex.

By this supply of ultrasonic or mega-sonic to the solution that contains fluoro-complex, homogeneity of the fine structure over the semiconductor material surface improves, and the formation rate can increase. Thus, the fine structure becomes less dependent on the surface morphology of the semiconductor material, and the productivity increases.

In the above-described fine structure formation method of the present invention, it is also preferable to add an additive chemical or a surfactant to the solution that contains the fluoro-complex.

By this addition of an additive chemical or a surfactant to the solution that contains the fluoro-complex, homogeneity of the fine structure over the semiconductor material surface improves. Thus, the fine structure becomes less dependent on the surface morphology of the semiconductor material, and the productivity increases.

It is also preferable in the present invention that the semiconductor materials be a bulk material, a thin film, an epitaxial film, a polycrystalline film, or an amorphous film which are made of Si, Ge, a SiGe mixture, or a compound semiconductor; and also the semiconductor materials be a semiconductor layer formed on a quartz, glass, or plastics. Thus, the fine structure of the present invention can be formed on various semiconductor materials.

In addition, in the fine structure formation method of the present invention, it is preferable to control the porosity to 10-80% of the bulk.

By this control of the porosity, the porosity of the fine structure on the semiconductor material surface can be set to the best range for each application. Thus, the fine structure of various purposes of the porosity in the desired range is obtained.

It is preferable to heat-treat the fine structure after forming the fine structure on the semiconductor material.

By this heat-treatment, the residual volatile components such as water are removed from the fine structure formed on the semiconductor material surface. Thus, the properties of the fine structure can be stabilized by the heat-treatment.

In the heat-treatment of the fine structure formed on the semiconductor material surface, temperatures higher than 300 degree centigrade (° C.) are preferable. Such temperatures are adequate to remove the residual volatile components by evaporation from the fine structure. Thus, the properties of the fine structure can be stabilized by the heat-treatment at such temperatures.

It is also preferable that the heat-treatment of the fine structure formed on the semiconductor material surface be performed in an oxidizing atmosphere. This heat-treatment in an oxidizing atmosphere causes oxidation of the fine structure on the semiconductor material surface. Thus, an oxidized region can be introduced in the fine structure formed on the semiconductor material. Moreover, the properties of the fine structure can be stabilized by the oxidation.

### BRIEF DESCRIPTION OF THE DRAWINGS

FIG. 1 shows a setup used for a porous layer (fine structure) formation in the conventional method (anodic reaction).

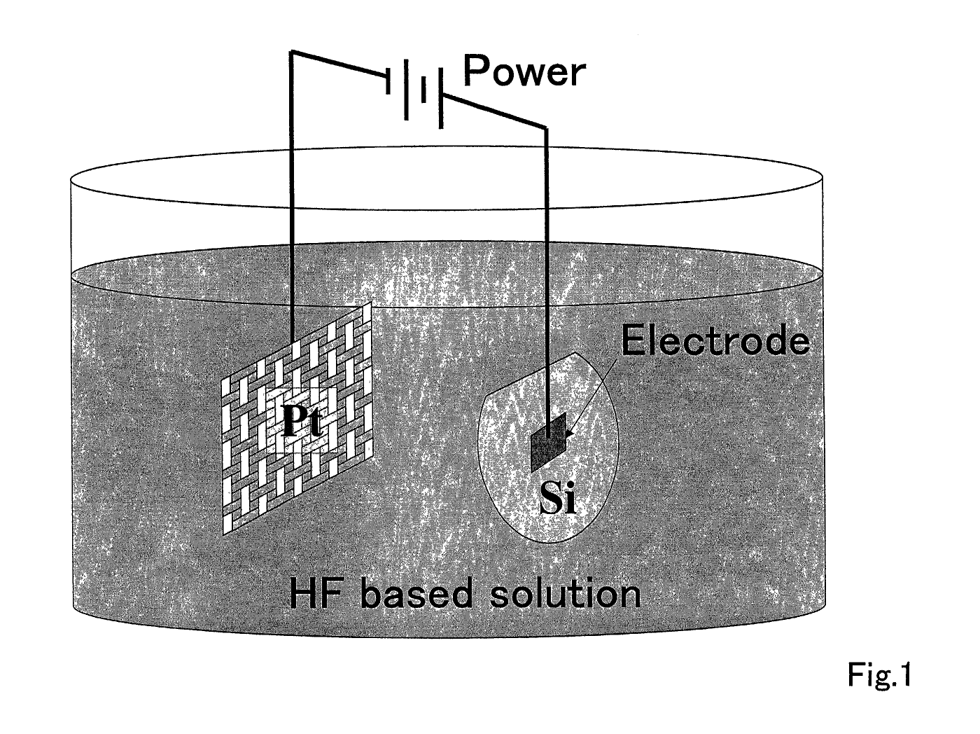

FIG. 2 is a schematic view showing the difficulty of the electrical current flow through Si on SiO₂ film in the conventional anodic reaction method for forming the porous layer (fine structure).

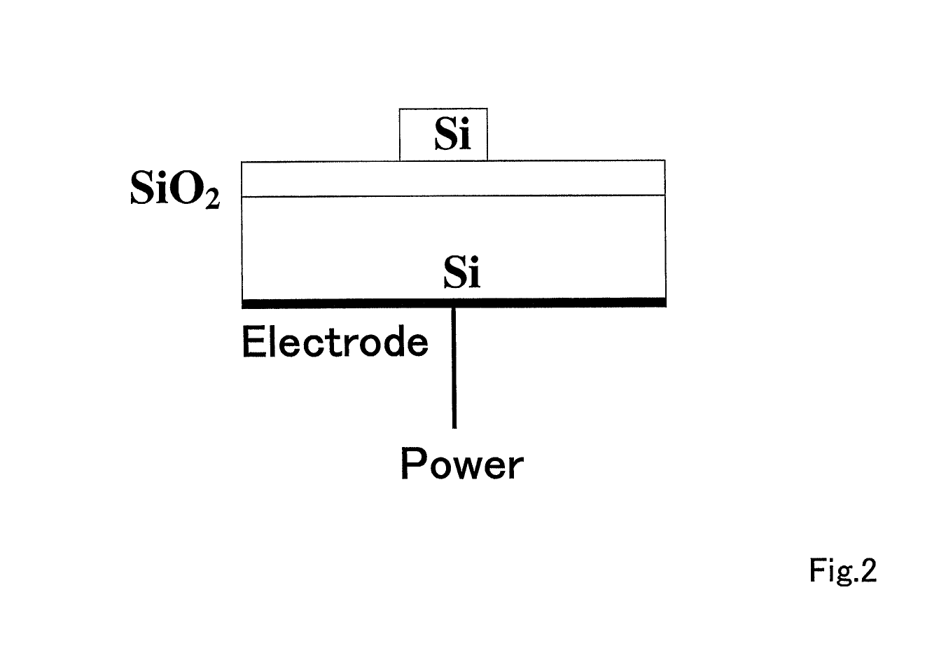

FIG. 3 shows a setup used for a porous layer (fine structure) formation according to the present invention.

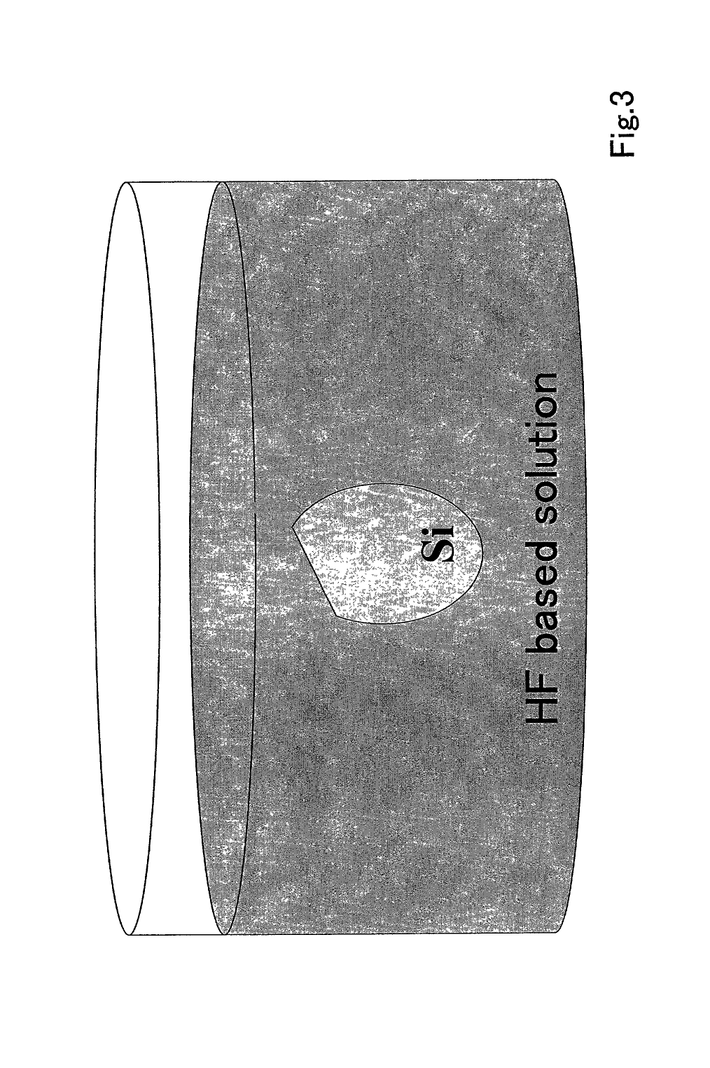

FIG. 4 is a schematic view showing that the electrical current flow is unnecessary in the method for the porous layer (fine structure) formation in the present invention.

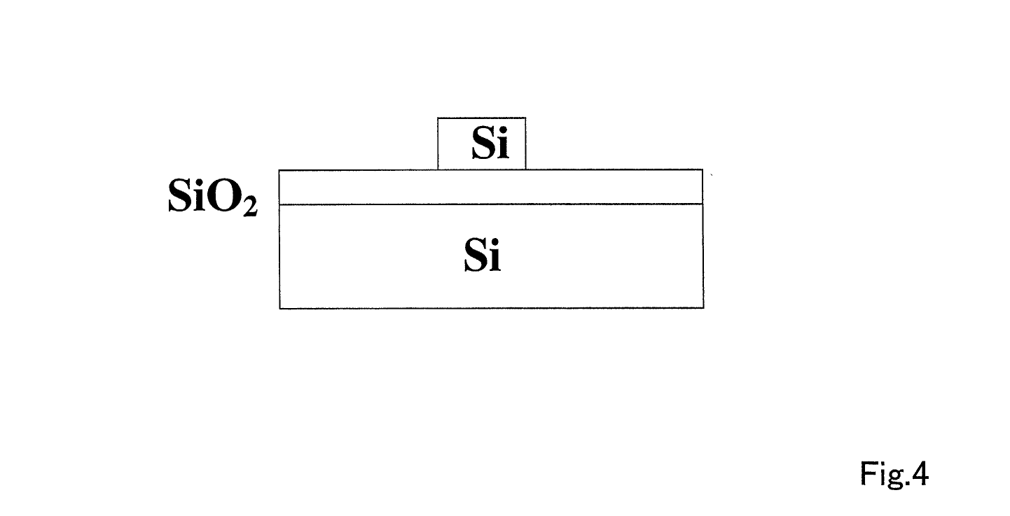

FIG. 5 is a scanning electron microscope (SEM) photograph of the fine structure formed on the semiconductor material surface by dipping a Si wafer for 16 hours in a mixture solution of the concentrated fluorotitanate solution (50 ml) and boric acid (4 g).

FIG. 6 is a graph showing the dipping time and the thickness of the fine structure layer formed on the semiconductor material surface by dipping a Si wafer in a mixture solution of the concentrated fluorotitanate solution (50 ml) and boric acid (4 g).

FIG. 7 is a scanning electron microscope (SEM) photograph of the fine structure formed on the semiconductor material surface by dipping a Si wafer for 16 hours in a solution of hydro fluoric acid (15 ml) with Fe₂O₃ (2 g) addition.

FIG. 8 is a scanning electron microscope (SEM) photograph of the fine structure formed on the semiconductor material surface by dipping a Si wafer for 16 hours in a solution of hydro fluoric acid (15 ml) with MnO₂ (0.5 g) addition.

FIG. 9 is a scanning electron microscope (SEM) photograph of the fine structure formed on the semiconductor material surface by dipping a polycrystalline Si film on SiO₂ film for 16 hours in a mixture solution of the concentrated fluorotitanate solution (50 ml) and boric acid (4 g).

FIG. 10 is a scanning electron microscope (SEM) photograph of the fine structure formed on the semiconductor material surface by dipping a Si wafer for 16 hours in a mixture solution of the concentrated fluorotitanate solution (50 ml) and boric acid (4 g) followed by heat-treatment at 900° C. for 30 minutes at an oxygen partial pressure of 0.5 atm.

FIG. 11 shows an X-ray photoelectron spectra (XPS) of the fine structure surface formed on the semiconductor material by dipping a Si wafer for 16 hours in a mixture solution of the concentrated fluorotitanate solution (50 ml) and boric acid (4 g) with and without subsequent heat-treatment at 900° C. for 30 minutes at an oxygen partial pressure of 0.5 atm (thermal oxidation), followed by introduction of the wafer into the XPS analytical vacuum chamber.

FIGS. 12A, 12B, 12C and 12D schematically show the steps to form a patterned fine structure of a polycrystalline Si film, where the polycrystalline Si film deposited on SiO₂ film is patterned into lines by the standard lithographic method (photo lithography) using a conventional photo-resist and an etching method (chlorine plasma etching) followed by resist removal and dipping of the polycrystalline Si film in a fluoro-complex solution.

FIGS. 13A, 13B, 13C and 13D schematically show the steps to form a patterned fine structure of a polycrystalline Si film, where the polycrystalline Si film deposited on SiO₂ film is masked (covered) with photo-resist patterned in lines by the standard lithographic method followed by dipping of the polycrystalline Si film in a fluoro-complex solution.

### DETAILED DESCRIPTION OF THE INVENTION

The present invention will be described in detail with reference to the preferred embodiments as follows:

### First Example

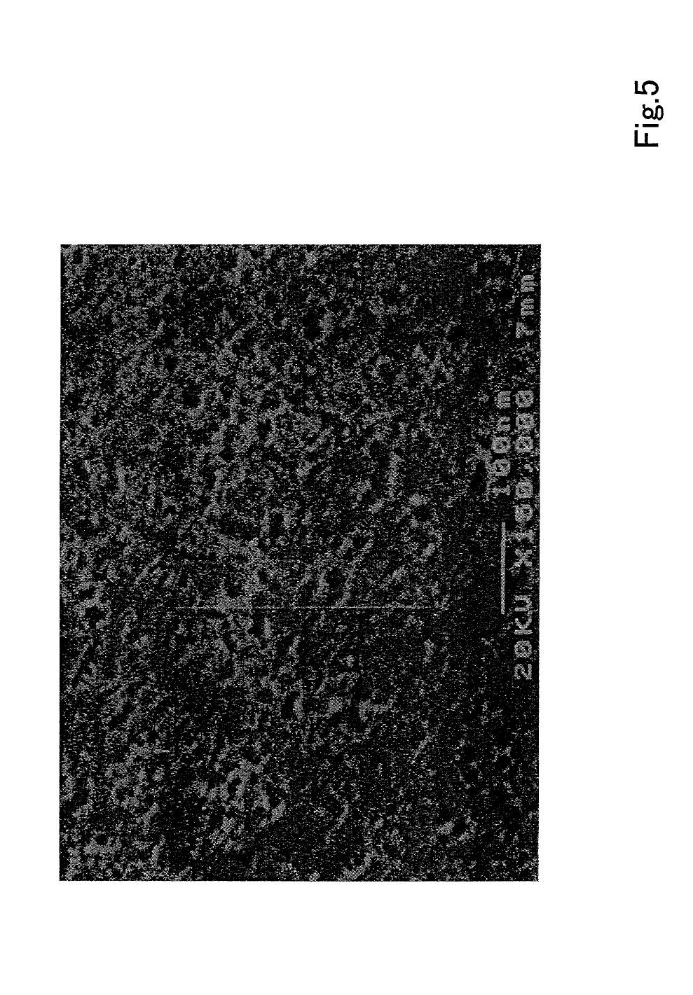

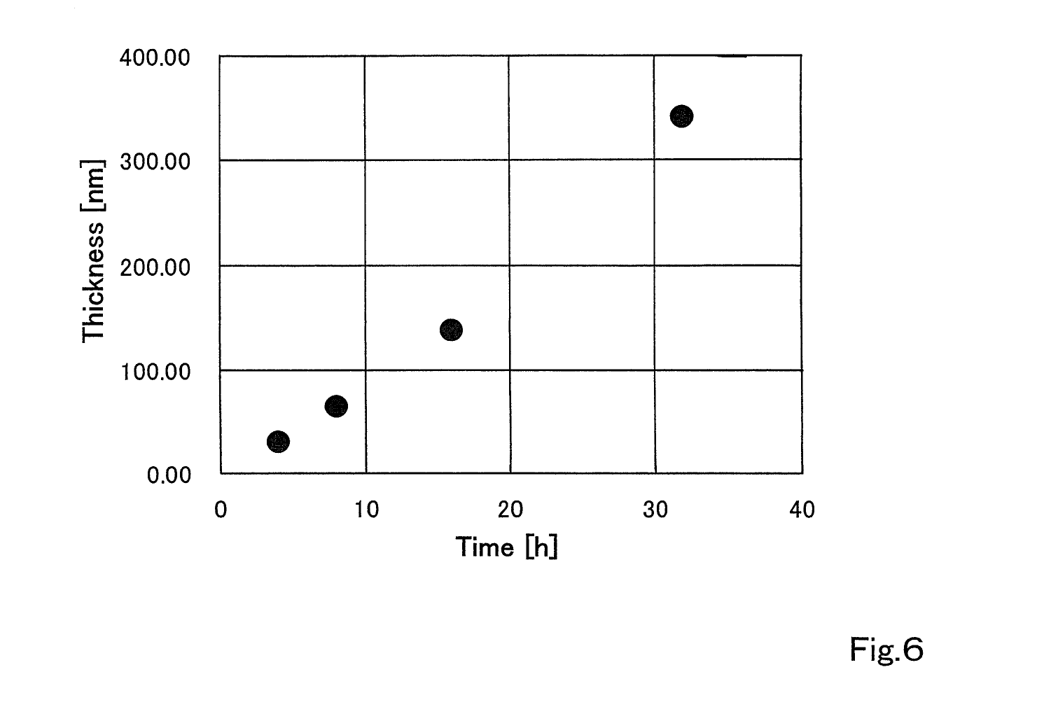

4 g of boric acid was added and dissolved in a 50 ml aqueous solution of concentrated fluorotitanate (hexafluorotitanate) to obtain a solution that contains fluoro-complex. In the resultant solution, a Si wafer which is a semiconductor material was dipped for 16 hours at 23° C. The resultant surface of the Si wafer became blue in color due to interference and was changed to be porous with a fine structure. The fine structure on the surface was observed by a scanning electron microscope (SEM) and is shown in FIG. 5, where a great number of fine pores are formed and observed. When the adding amount of boric acid was ranged from 0 g to 10 g, then a similar surface fine structure was observed, but the 4 g-addition was the best for thickness homogeneity and controllability. When the dipping solution was warmed up to 35° C., then the thickness of the porous structure formed on the surface was doubled, proving that a faster processing was performed at a higher temperature. The relationship between the dipping time and the thickness of the fine structure layer formed on the semiconductor material surface is shown in FIG. 6. It can be seen from FIG. 6 that the thickness of the formed fine structure layer increases as the dipping time becomes loner, indicating that the reaction proceeds.

In this First Example, a commercially available aqueous solution of concentrated fluorotitanate was used for the convenience as a solution that contains fluoro-complex. But, the same effect is obtained when a solution obtained by dissolving Ti, Titanium alloy or Titanium-containing compound in a hydrofluoric acid is used. Also, the same effect is obtained when a solution obtained by mixing fluoro-complex with a strong acid to form equivalent contents of solution is used.

### Second Example

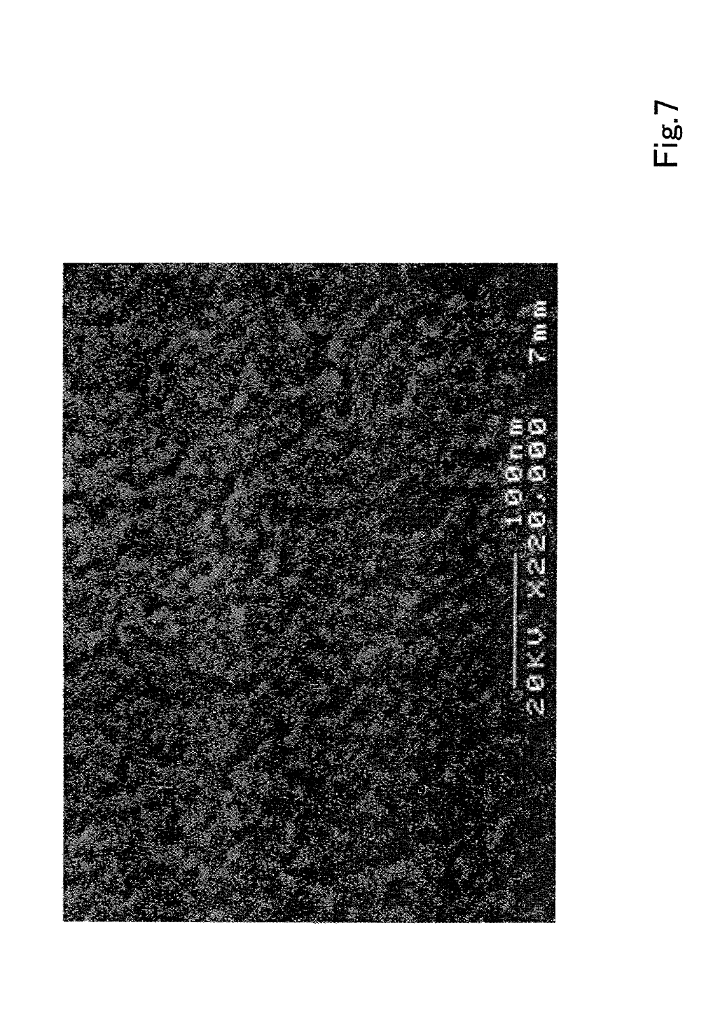

2 g of Fe₂O₃ as a compound containing a metallic element Fe was added to 15 ml of hydrofluoric acid and dissolved partly to concoct a solution that contains fluoro-complex. In the obtained solution, a Si wafer which is a semiconductor material was dipped for 16 hours at 23° C. The resultant surface of the Si wafer became blue-green in color due to interference and was changed to be porous with a fine structure. The fine structure on the surface observed by a scanning electron microscope (SEM) is shown in FIG. 7, where a great number of fine pores are formed and observed.

### Third Example

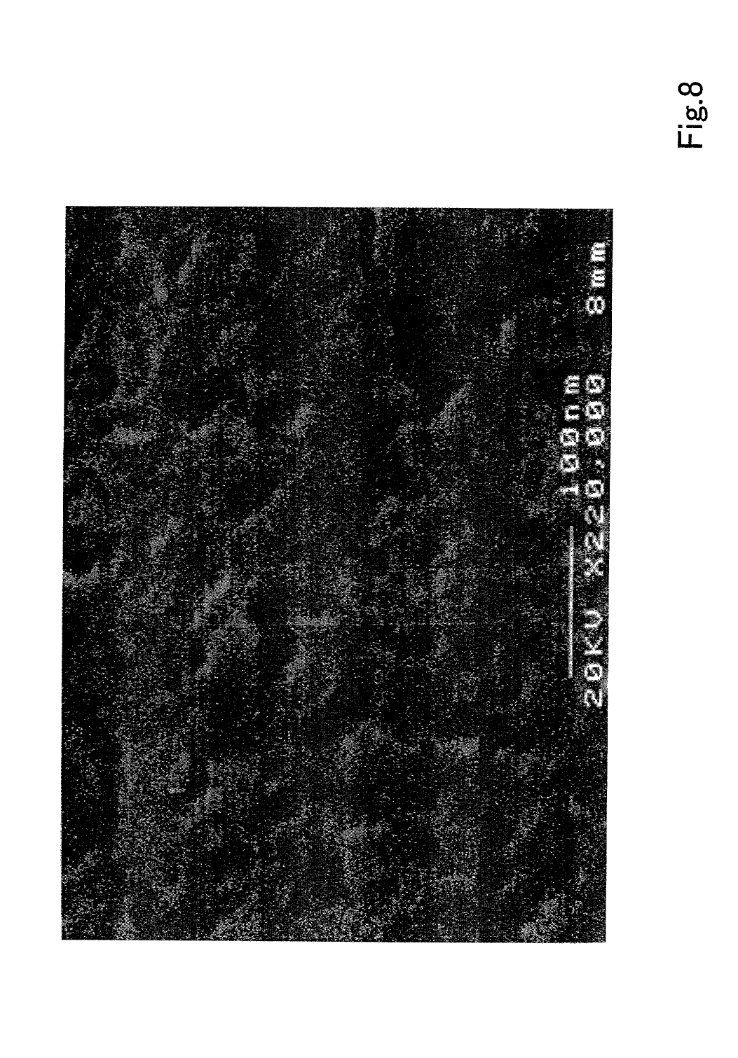

0.5 g of MnO₂ as a compound containing a metallic element Mn was added to 15 ml of hydrofluoric acid and dissolved partly to concoct a solution that contains fluoro-complex. In the obtained solution, a Si wafer which is a semiconductor material was dipped for 16 hours at 23° C. The resultant surface of the Si wafer became gold-colored due to interference and was changed to be porous with a fine structure. The fine structure on the surface observed by a scanning electron microscope (SEM) is shown in FIG. 8, where a great number of fine pores are formed and observed.

In the Second and Third Examples, the mostly convenient commercial reagents, Fe₂O₃ and MnO₂, respectively, were added to hydrofluoric acid so as to obtain a solution that contains fluoro-complex. However, these reagents can be replaced by a metallic element such as Zr and Hf, by an alloy containing such metallic elements (Zr and Hf), and by a compound with such metallic elements (Zr and Hf).

### Fourth Example

4 g of boric acid was added and dissolved in a 50 ml aqueous solution of concentrated fluorotitanate. In the obtained solution, a Si wafer and Si_{0.8}Ge_{0.2}, Si_{0.5}Ge_{0.5}, and Ge epitaxial films deposited on Si wafers were dipped for 16 hours at 23° C. The resultant surface became gold-colored due to interference and was changed to be porous with a fine structure.

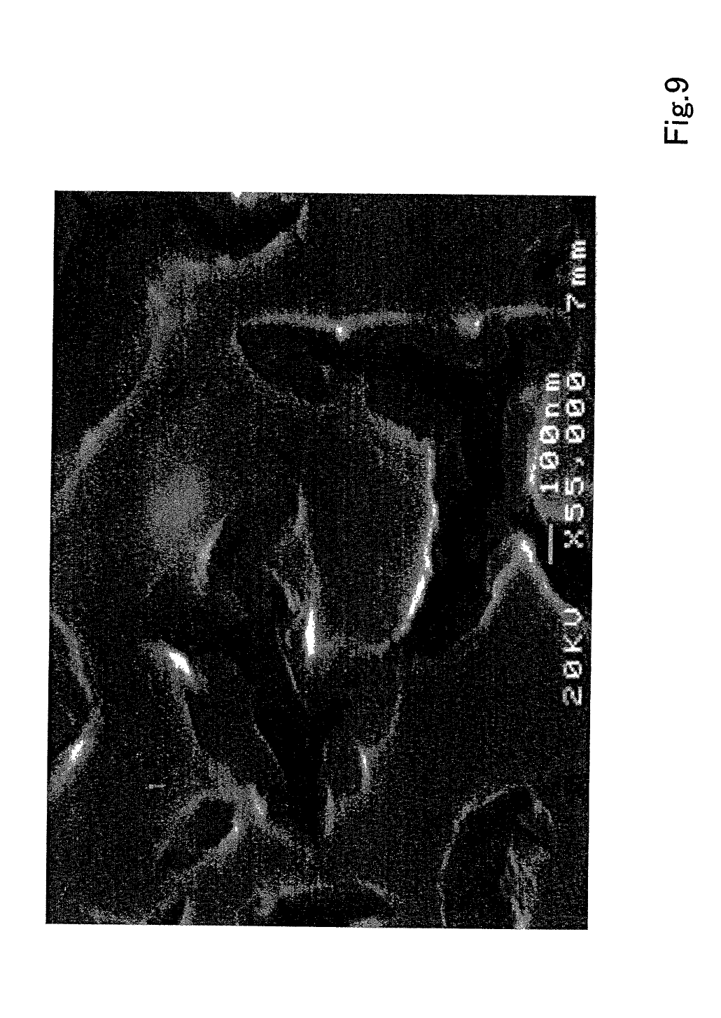

When a polycrystalline Si film formed on SiO₂ film was dipped for 16 hours at 23° C. in the above-described boric acid added solution, the resultant surface changed so as to be very porous as seen from FIG. 9.

Thus, a surface fine structure can be easily formed on various semiconductor materials.

### Fifth Example

In the above First through Fourth Examples, dipping of the semiconductor materials in the solution was carried out under fluorescent light in a laboratory room. On the other hand, in the Firth Example, a process similar to that in the First Example was carried out by shading the light by covering the whole beaker that contains the solution and Si wafer inside. The result was that the formed thickness of the fine structure on the semiconductor material surface decreased to 70% of that without the shading. Thus, the reaction under the light exposure causes a better control of forming of the fine structure on the semiconductor material surface. Especially, it was confirmed that the higher energy (shorter wave length) than that necessary for inducing an inter-band transition is effective for the formation of the fine structure on the surface of the semiconductor material.

### Sixth Example

In the above First Example, gas is generated by the reaction occasionally to become fine bubbles, and the bubbles attach to the wafer surface, suppressing the reaction at the attached part. Thus, the homogeneity degrades on the fine structure formed on the semiconductor material surface. This degradation of homogeneity is easily observed as a different interference color by the naked eye.

So as to avoid degradation of homogeneity, a process similar to that in the First Example was carried out by way of supplying ultrasonic waves to a beaker that contains the solution and Si wafer by an ultrasonic bath. As a result, a surface structure with an improved homogeneity was obtained.

Also, by way of adding ethanol to the mixture solution used in the First Example, an improved homogeneity was obtained.

In the above Examples, ultrasonic and ethanol additions are the most convenient. However, the effects are not limited to these additions; and mega-sonic and other surfactants, which suppress the attachment of the bubbles, can be effective for the fine structure formation on the semiconductor material surface.

### Seventh Example

In the Seventh Example, the semiconductor materials, mixture solutions and/or dipping conditions were changed. By these changes, depending on the semiconductor material, the mixture solution and the dipping condition, as shown in FIGS. 5, 6, 7, 8 and 9, the thickness, the pore diameter and the porosity was controlled easily.

Moreover, due to the porosity change, the refractive index of the film was changed. A 10-80% porosity was effectively convenient for refractive index application.

### Eighth Example

A fine structure, which was formed on a Si wafer by the method described in the Fourth Example, was heat-treated at 900° C. for 30 minutes and at 0.5 atm oxygen partial pressure.

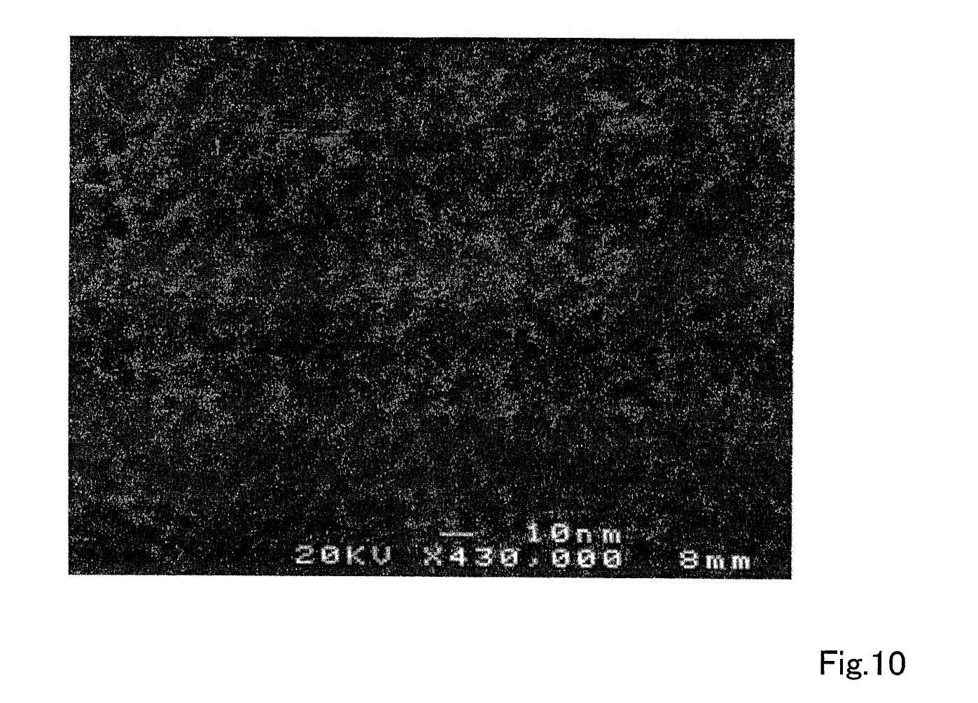

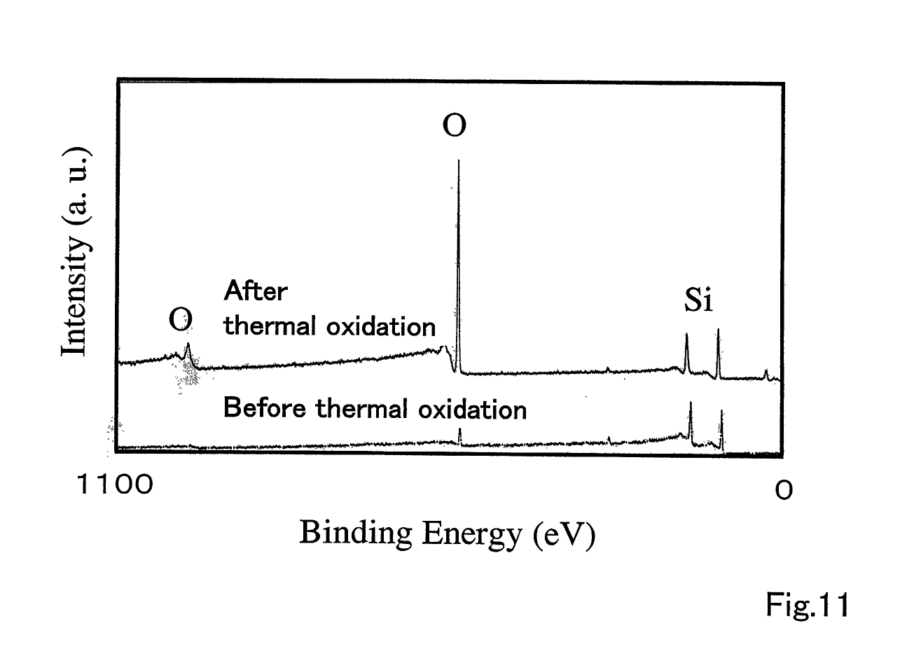

The resultant surface of the Si wafer observed by a scanning electron microscope (SEM) is shown in FIG. 10, where it is seen that the formed micro-pores remain little-changed after the oxidation. It is confirmed from FIG. 11 that the Si surface is oxidized.

Thus, a heat-treatment in an oxidizing ambient causes oxidation of each micro-pore surface of the fine structure of the semiconductor material surface. This means that a fine structure of a semiconductor covered with oxide on its surface is formed easily by the above method.

In the above Examples, a typical heat-treatment condition was used, but other conditions with different temperatures and oxidizing ambient are effective for forming the fine structure depending on the condition. Moreover, the analysis indicates that residual components of the solution were evaporated more thoroughly at a heat-treatment temperature higher than 300° C. even in an environmental atmosphere.

### Ninth Example

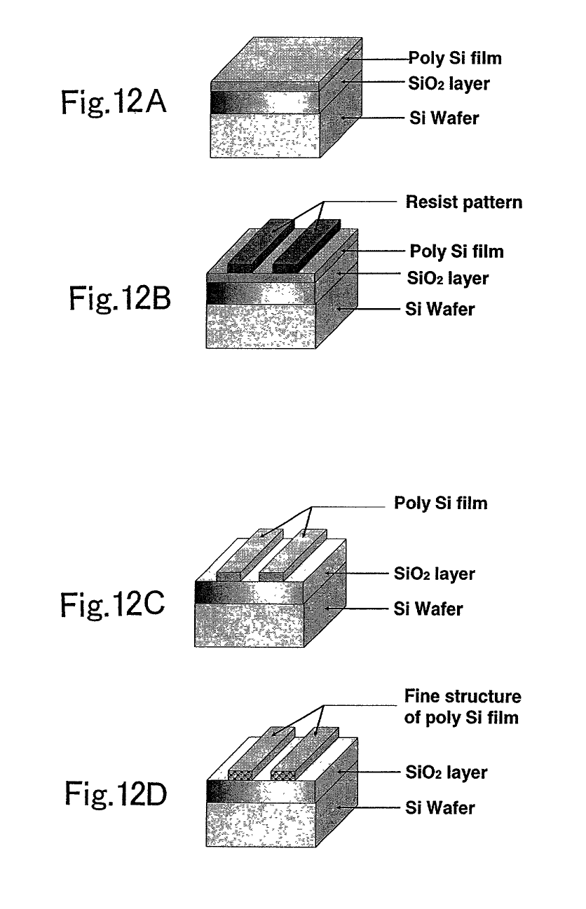

By the steps shown in FIGS. 12A through 12D, a polycrystalline Si film deposited on SiO₂ film is patterned into lines by the standard lithographic method (photo lithography) using the conventional photo-resist and by the etching method (chlorine plasma etching), and a resist removal was performed, and then the polycrystalline Si film was dipped in a mixture solution of the concentrated fluorotitanate solution (50 ml) and boric acid (4 g). A fine structure is formed even where the polycrystalline Si film was patterned. Thus, it is possible to form a fine structure only in [the] a defined region that is, for instance, patterned in advance.

In this Ninth Example, the most standard photolithography and chlorine plasma etching were used for patterning. But, other patterning methods such as electron beam lithography, wet-chemical etching, and a lift-off method are applicable. Moreover, the pattern is not limited to lines, and various patterns can form their dependent fine structure pattern.

Moreover, in this Ninth Example, the semiconductor material used is a polycrystalline Si film deposited on SiO₂ film. However, this method can be easily applied to a surface Si layer of the SOI (Silicon On Insulator) wafer to form a fine structure on its surface. These Si layers on SiO₂ films are applicable to a photonic waveguide based on the refractive index difference optics.

### Tenth Example

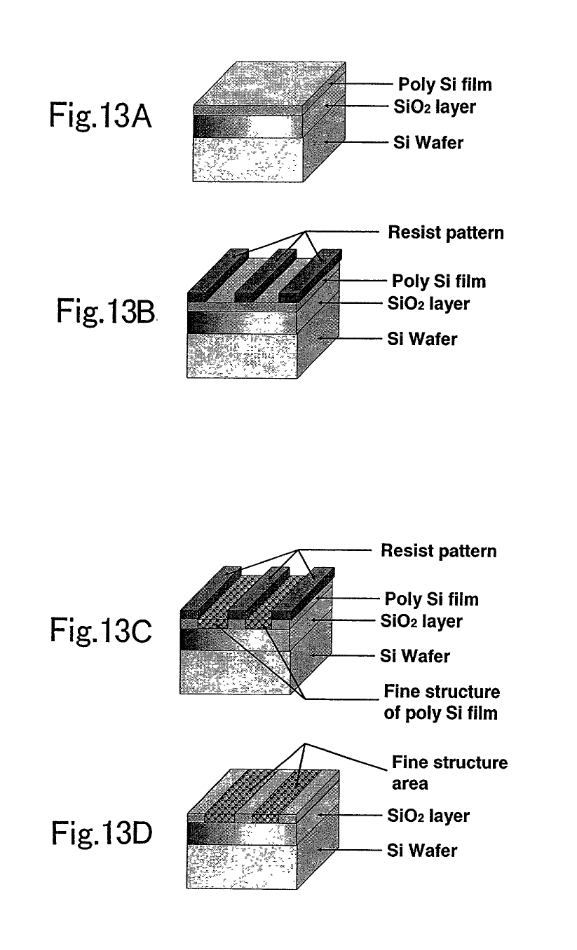

By the steps shown in FIGS. 13A through 13D, on the polycrystalline Si film deposited on SiO₂ film, a resist pattern of lines is formed by the standard photolithography using a commercially available photo-resist (TSMR-8900). Using the patterned photo-resist as a mask (covering material), the polycrystalline Si film was dipped in a mixture solution of the concentrated fluorotitanate solution (50 ml) and boric acid (4 g). A fine structure is formed only where the polysilicon layer is contacted with the solution through the pre-patterned resist.

In this Tenth Example, the most standard photolithography was used for patterning. But, other patterning methods such as electron beam lithography, or other coating materials or masking materials such as thin films are applicable. Depending on the mask pattern, a patterned fine structure can be formed easily.

Moreover, in this Tenth Example, the semiconductor material used is a polycrystalline Si film deposited on SiO₂ film. However, this method can be easily applied to a surface Si layer of the SOI (Silicon On Insulator) wafer to form a fine structure on its surface. These silicon layers on SiO₂ films are applicable to a photonic waveguide based on the refractive index difference optics.

### Eleventh Example

On a Si wafer, a p-type high concentration region doped with 1×10²⁰ cm⁻³ Boron and a n-type high concentration region doped with 1×10²⁰ cm⁻³ Phosphorus were formed. The obtained wafer was dipped in a mixture solution of the concentrated fluorotitanate solution (50 ml) and boric acid (4 g). A fine structure (porous layer) is formed over a thickness larger than 150 nm in the n-type region, while only a 10 nm or less thick region is changed into a fine structure (porous layer) in the p-type region. Accordingly, the conductivity of the n-type region decreased to about 10% of that before the formation of the fine structure (porous layer), while the conductivity of the p-type region was almost the same as that before the formation.

As seen from the above, a fine structure with regions of different conductivity or different conduction type or different porosity is formed on the same semiconductor material surface. The thickness and conductivity of the fine structure layer changes systematically with the doped impurity type and concentration, and the properties of the fine structure (porous layer) are controlled continuously.

The above-described Examples are of the most representative ones. Various applications are possible where a fine structure is formed on the semiconductor material surface. Thus, a semiconductor material on which the fine structure (porous layer) is formed can be obtained without using electrical current. Optical devices, electronic devices and opto-electronic devices can be manufactured easily by using such a fine structure (porous layer).

What is claimed is:

1. A method for forming a fine structure on a semiconductor material surface by way of contacting said semiconductor material surface with a solution that contains fluoro-complex.

2. The method for forming a fine structure on a semiconductor material surface according to claim 1, wherein said solution that contains fluoro-complex is obtained by dissolving in a hydrofluoric acid at least one selected from the group consisting of:
a metallic element,
alloys containing said metallic element, and
compounds containing said metallic element.

3. The method for forming a fine structure on a semiconductor material surface according to claim 2, wherein said metallic element is one selected from the group consisting of Ti, Mn, Fe, Zr, and Hf.

4. The method for forming a fine structure on a semiconductor material surface according to claim 1, wherein said solution that contains fluoro-complex, is:
one of solutions selected from the group consisting of fluorotitanate, fluoromanganate, fluoroferrate, fluorozirconate, fluorohafnate, and a mixture of said fluorotitanate, fluoromanganate, fluoroferrate, fluorozirconate, fluorohafnate, or
a solution obtained by dissolving at least one selected from the group consisting of ammonium salts, alkaline metallic salts and alkaline earth metallic salts of fluorotitanate, or fluoromanganate, or fluoroferrate, or fluorozirconate, or fluorohafnate.

5. The method for forming a fine structure on a semiconductor material surface according to claim 1, 2, 3 or 4, wherein said solution that contains fluoro-complex, further containing boric acid or a material which is effective for bonding with fluorine in said solution that contains fluoro-complex,

6. The method for forming a fine structure on a semiconductor material surface according to claim 1, 2, 3 or 4, further comprising the step of forming a pattern on said semiconductor material surface, said step being performed before contacting said semiconductor material surface with said solution that contains fluoro-complex.

7. The method for forming a fine structure on a semiconductor material surface according to claim 1, 2, 3 or 4, further comprising the step of forming a mask pattern on said semiconductor material surface, said step being performed before contacting said semiconductor material surface with said solution that contains fluoro-complex.

8. The method for forming a fine structure on a semiconductor material surface according to claim 1, 2, 3 or 4, further comprising at least one of the steps of:
forming one or both of a p-type region and an n-type region on said semiconductor material surface, and
forming regions of different impurity concentrations on said semiconductor material surface, wherein
said at least one of said steps being performed before contacting said semiconductor material surface with said solution that contains fluoro-complex.

9. A semiconductor material provided with a fine structure that is formed by said fine structure formation method according to claim 1, 2, 3 or 4.

10. A device made of a semiconductor material on which a fine structure is formed by said fine structure formation method according to claim 1, 2, 3 or 4.
